(19) United States
(12) Patent Application Publication
(10) Pub. No.: US 2023/0040740 A1
(43) Pub. Date: Feb. 9, 2023

(54) METHOD FOR PRODUCING A CONDUCTIVE PATTERN ON A SUBSTRATE

(71) Applicant: DIGITAL TAGS FINLAND OY, Tampere (FI)

(72) Inventors: Lauri HUHTASALO, Tampere (FI); Kaj BACKFOLK, Villmanstrand (FI)

(73) Assignee: DIGITAL TAGS FINLAND OY, Tampere (FI)

(21) Appl. No.: 17/786,943

(22) PCT Filed: Dec. 17, 2020
(86) PCT No.: PCT/IB2020/062113

§ 371 Date: Jun. 17, 2022

(30) Foreign Application Priority Data
Dec. 20, 2019 (SE) 1951520-4

(51) Int. Cl. H05K 3/10; H01Q 1/22; H05K 3/12

(52) U.S. Cl. CPC H05K 3/102; H01Q 1/2225; H05K 3/1283; H05K 2201/10098; H05K 2203/0278; H05K 2203/1105

(57) ABSTRACT

Method for producing an electrically conductive pattern on a substrate, wherein the method comprising the steps of forming an adhesive layer in a predetermined pattern on a substrate, adding electrically conductive solid particles onto the adhesive layer, wherein the particles stick onto the adhesive, heating the solid particles with electromagnetic radiation wherein the wavelengths of the electromagnetic spectrum are in the range 600-1400 nm, preferably in the range 700-1200 nm, such that the temperature of the particles exceeding their characteristic melting point, and pressing the heated particles against the substrate in a nip, wherein the particles are flattened, such that the particles electrically connect to each other and thereby form the conductive pattern.

### TECHNICAL FIELD

The present invention relates to a method for producing an electrically conductive pattern on a substrate and a method for producing an RFID tag.

### PRIOR ART—PROBLEM

It is known to form a conductive pattern on a substrate, wherein solid conductive particles are formed into a predetermined pattern on the substrate. Thereafter, the solid particles are heated by thermal heating, typically in an oven, wherein the solid particles reach a temperature above their characteristic melting point. The particles are then pressed in a nip such that the particles are flattened wherein the particles electrically connect to each other and thereby form the conductive pattern.

A drawback with this method is that not only the solid particles, but also the substrate absorbs heat during the heating process. This may cause problem, for example a fiber-based substrate will dry when heated. This will lead to unwanted dimensional changes of the substrate. Moreover, if heated to too high temperature, the fibers can start change color towards brown or even burn. In addition, the thermal heating has a relatively high energy consumption.

### OBJECT OF INVENTION

An object with the invention is to provide a method to produce an electrically conductive pattern on a substrate that at least partly solves the above-mentioned problem.

### SUMMARY OF THE INVENTION

The invention is a method for producing an electrically conductive pattern on a substrate, wherein the method comprising the steps of:
forming an adhesive layer in a predetermined pattern on a substrate, made of at least one of a cellulose material and a polymer material,
adding electrically conductive solid particles onto the adhesive layer, wherein the particles stick onto the adhesive,
heating the solid particles with electromagnetic radiation wherein the wavelengths of the electromagnetic spectrum are in the range 600-1400 nm, preferably in the range 700-1200 nm, such that the temperature of the particles exceeding their characteristic melting point, and
pressing the heated particles against the substrate in a nip, wherein the particles are flattened, such that the particles electrically connect to each other and thereby form the conductive pattern.

Moreover, the invention is a method for producing an RFID tag, wherein the method comprising the steps of:
forming an adhesive layer in a predetermined pattern on a substrate made of at least one of a cellulose material and a polymer material,
adding electrically conductive solid particles onto the adhesive layer, wherein the particles stick onto the adhesive,
heating the solid particles with electromagnetic radiation wherein the wavelengths of the electromagnetic spectrum are in the range 600-1400 nm, preferably in the range 700-1200 nm, such that the temperature of the particles exceeding their characteristic melting point, and
pressing the heated particles against the substrate in a nip, wherein the particles are flattened, such that the particles electrically connect to each other and thereby form an antenna, and
attaching an integrated circuit (IC) onto the antenna, such that an electrical connection between the IC and the antenna is established, wherein the antenna and the IC form the RFID tag.

### DETAILED DESCRIPTION OF THE INVENTION

The inventive method for producing an electrically conductive pattern on a substrate will hereinafter be described more in detail with reference to some preferred embodiments.

The method comprising a step of forming an adhesive layer in a predetermined pattern on a substrate. The adhesive pattern can be applied by any suitable method for applying an adhesive pattern onto a substrate e.g. inkjet, flexo printing, letterpress printing, gravure printing, screen printing, spraying, web coating, wheel applying, brushing or any other method capable of depositing an adhesive pattern on the substrate is included. The adhesive may be any suitable adhesive for the purpose. A preferred adhesive is an acrylic based adhesive e.g. styrene/acrylate, styrene/butadiene or PVAc emulsions. The adhesive could also be starch based adhesive such as modified starch.

The substrate may be a paper or paperboard material, since these cellulose materials have very good adhesive properties of the conductive pattern. Moreover, paper and paperboard are eco-friendly, since they are biodegradable and recyclable. A preferred substrate is a cellulose substrate with a grammage from 30 to 200 gsm. Moreover, the substrate may be a single or multiply substrate. Another suitable cellulose substrate is a substrate made of microfibrillated cellulose (MFC) or a film made of microfibrillated cellulose.

However, the skilled person realizes that other, non-conductive, substrates are possible such as polyester taffeta or nylon. These polymer substrates are especially suitable if the product will be used in a wet environment e.g. a care label in clothes which contain washing instructions. These polymers are highly sensitive to heat, so the invention is very suitable for these materials as well. The skilled person also realizes that the substrate may be made of a combination of a cellulose material and a polymer material.

The method further comprises the step of adding electrically conductive solid particles onto the adhesive layer pattern, wherein the particles stick onto the adhesive. The solid particles may be applied in several different ways and the invention is not limited to a specific application method. For example, the applying steps may be blowing the solid particles onto the adhesive, dipping the substrate onto a bed of particles wherein the particles stick onto the adhesive pattern or by electrostatic transferring.

The electrically conductive solid particles are preferably made of a solder material of a non-eutectic alloy. However, most preferred is an alloy comprising tin and bismuth or only tin. Tin and bismuth are lead-free and are therefore more environmentally friendly. Moreover, they have a relatively low melting temperature and relatively good electrical conductivity.

The method also comprising at least one step of heating. The heating is performed by heating the solid particles with electromagnetic radiation wherein the wavelengths of the electromagnetic spectrum are in the range 600-1400 nm, preferably in the range 700-1200 nm, such that the temperature of the particles exceeding their characteristic melting point.

The energy emission of the electromagnetic radiation is in the range 1.5-2.8 MW/μm m².

Tests have shown that electromagnetic radiation at these short wavelengths are very suitable for heating/melting the solid solder particles of a non-eutectic alloy. In this region the radiation excites combinations and overtones of molecular vibrations. This means that the molar absorptivity is typically small in this part of the electromagnetic spectrum with the consequence that many polymer compounds do not have a strong absorbance and thereby do not heat up easily when irradiated with such short electromagnetic radiation wavelengths. The electromagnetic radiation with these short wavelengths has the potential to selectively heat a material with a strong absorbance in this part of the spectrum and its inherent energy density would enable high speed, whilst the underlaying substrate will allow penetration of the radiation through it thus avoiding damage. The electromagnetic radiation having these short wavelengths is also known as Near Infrared or NIR. The electromagnetic radiation may be applied directly onto frontside of the substrate that faces against the solid particles or onto the backside of the substrate that faces away from the solid particles or simultaneously on both sides of the substrate.

Hence, paper, fiber-based substrates and most common plastic packaging do not significantly absorb radiation at these at these short wavelengths. This means that unnecessary heating of the substrates which indirectly causing negative effects to the substrates made of paper, paper board, polyester and nylon is very much decreased.

The method also comprises the step of pressing the heated particles against the substrate. The pressure is performed in a nip and the surface temperature of the nip is lower than the characteristic melting temperature of the particles. The pressure of the nip will make the particles flattened, such that the particles electrically connect to each other and thereby form a conductive pattern.

This pressure is preferably applied relatively soon after the radiation heating, wherein the particles still remain in almost melted state. Hereby, the previously melted material to solidify in the form an essentially continuous, electrically conductive pattern.

The nip may be a non-heated nip. However, preferably, the nip surface is heated into a temperature somewhat (such as 30-60° C.) lower than the characteristic melting temperature. This ensures for example that the melt will not solidify prematurely, before it would become pressed against the substrate. The nip will cause the previously molten material of the originally solid electrically conductive particles to solidify again, but this time not in the form of separate particles but in the form of an essentially continuous, electrically conductive layer, arranged in the predetermined pattern.

The method may also involve an embodiment of one or several additional heating steps. These additional heating steps may be arranged before and/or after the electromagnetic radiation step with short wavelengths.

The additional heating step may be an infrared radiation (IR) heating with a wavelength from 1500 nm and above. The IR source is preferably 2×2 kW IR lamps or 4×2 kW IR lamps. A preferred embodiment is IR with a wavelength from 1500 nm and above after the step electromagnetic radiation with wavelengths the range 600-1400 nm.

The additional heating step may also be thermal heating in an oven. The temperature of the oven is below 200° C.

The additional heating steps may be favourable since a conductor can have geometries with various shapes and sizes. The combination of the different heating steps may all heat the different geometrical shapes differently. E.g. one heating method heats first the narrow shapes or edges of solid patterns, whereas some other heating method may first heat the centre of the solid pattern. Therefore, it may be beneficial to accompany the inventive electromagnetic radiation heating step (wavelengths 600-1400 nm) with IR and/or thermal heating to reach balanced and uniform heating profile of variable geometric shapes.

In a preferred embodiment of the invention the formed conductive pattern is an antenna, preferably an antenna for an RFID tag.

In another embodiment the invention comprises a method for producing an RFID tag. This embodiment the same as the embodiments above and, in addition, comprises the step of attaching an integrated circuit (IC) or microchip to the conductive pattern, i.e. the antenna, such that an electrical connection between the IC and the antenna is established, wherein the antenna and the IC form the RFID tag.

The attachment of the IC to the antenna may be performed in various way. In a first embodiment the IC is attached to the antenna by applying an adhesive between the IC and the antenna pad area and pressing the IC onto the RFID antenna. In a second embodiment the IC is attached via soldering.

Some benefits with the method in accordance with the invention in comparison to prior art:
The substrate will absorb less heat which means less risk of a damaged substrate.
The energy consumption will be reduced since the heat is directed where it is needed.
Even if additional heat is used, the energy consumption will be reduced thanks to the inventive heating step.
The inventive method enables that heat sensitive substrates can be used.
A substrate made of cellulose and/or polymer do not significantly absorb radiation at these short wavelengths. This means that unnecessary heating of the substrate is very much decreased, since it has been showed that heating and cooling of the substrate increases stresses in the substrate which might lead to cracks etc.

In the foregoing, the invention has been described based on some preferred embodiments. However, a person skilled in the art realises that additional embodiments and variants are possible within the scope of the following claims.

For example, the invention is not only applicable for producing an antenna for an RFID tag. The skilled person realizes that the inventive method is applicable in producing other conductive patterns such as e.g. printed wiring, conductor for flexible batteries, displays, sensors, heaters or similar.

1-14. (canceled)

15. Method for producing an electrically conductive pattern on a substrate, wherein the method comprising the steps of:
forming an adhesive layer in a predetermined pattern on a substrate made of at least one of a cellulose material and a polymer material,
adding electrically conductive solid particles onto the adhesive layer, wherein the particles stick onto the adhesive,
heating the solid particles with electromagnetic radiation wherein the wavelengths of the electromagnetic spectrum are in the range 600-1400 nm, preferably in the range 700-1200 nm, such that the temperature of the particles exceeding their characteristic melting point, and
pressing the heated particles against the substrate in a nip, wherein the particles are flattened, such that the particles electrically connect to each other and thereby form the conductive pattern.

16. Method according to claim 15, wherein the method further comprising at least one additional heating step in which the particles are heated to a temperature below the characteristic melting point.

17. Method according to claim 16, wherein the additional heating step is heating with infrared radiation heating wherein the wavelength of the IR source is from 1500 nm and above.

18. Method according to claim 16, wherein the additional heating step is thermal heating in an oven, wherein the temperature of the oven is below 200° C.

19. Method according to claim 15, wherein the energy emission of the electromagnetic radiation is in the range 1.5-2.8 MW/pm m².

20. Method according to claim 15, wherein the solid particles are made of a eutectic alloy.

21. Method according to claim 20, wherein the eutectic alloy comprises tin, preferably tin and bismuth.

22. Method according to claim 15, wherein substrate is made of paper or paper board material.

23. Method according to claim 15, wherein the substrate is made of polyester or nylon.

24. Method according to claim 15, wherein the conductive pattern is an antenna.

25. Method according to claim 24, wherein the method further comprising the step of attaching an integrated circuit (IC) onto the antenna, such that an electrical connection between the IC and the antenna is established, wherein the antenna and the IC form an RFD tag.

26. Method for producing an RFD tag, wherein the method comprising the steps of:
forming an adhesive layer in a predetermined pattern on a substrate made of at least one of a cellulose material and a polymer material,
adding electrically conductive solid particles onto the adhesive layer, wherein the particles stick onto the adhesive,
heating the solid particles with electromagnetic radiation wherein the wavelengths of the electromagnetic spectrum are in the range 600-1400 nm, preferably in the range 700-1200 nm, such that the temperature of the particles exceeding their characteristic melting point, and
pressing the heated particles against the substrate in a nip, wherein the particles are flattened, such that the particles electrically connect to each other and thereby form an antenna, and
attaching an integrated circuit (IC) onto the antenna, such that an electrical connection between the IC and the antenna is established, wherein the antenna and the IC form the RFID tag.

27. Method according to claim 26, wherein the integrated circuit (IC) is attached by gluing and pressing the IC onto the antenna.

28. Method according to claim 26, wherein the integrated circuit (IC) is attached by soldering.
